(19) United States
(12) Patent Application Publication
(10) Pub. No.: US 2012/0216745 A1
(43) Pub. Date: Aug. 30, 2012

(54) SPIN CHUCK AND APPARATUS HAVING SPIN CHUCK FOR MANUFACTURING PIEZOELECTRIC RESONATOR PIECE

(76) Inventor: Hirokazu Mizonobe, Chiba-shi (JP)

(21) Appl. No.: 13/372,678

(22) Filed: Feb. 14, 2012

(30) Foreign Application Priority Data
Feb. 24, 2011 (JP) 2011-038831

(51) Int. Cl. H01L 41/22; B05C 13/00

(52) U.S. Cl. 118/500

(57) ABSTRACT

A spin chuck rotating a substrate utilizing a centrifugal force while holding one surface of the substrate with a substrate holding section to apply a film material to another surface of the substrate. The substrate holding section includes a tapered peripheral part having a peripheral edge where a substrate holding surface and a back surface thereof are connected. The other surface of the substrate and the back surface of the substrate holding section smoothly continue with each other with the holding surface of the substrate holding section kept in contact with the other surface of the substrate.

### RELATED APPLICATIONS

This application claims priority under 35 U.S.C. §119 to Japanese Patent Application No. 2011-038831 filed on Feb. 24, 2011, the entire content of which is hereby incorporated by reference.

### BACKGROUND OF THE INVENTION

1. Field of the Invention

The present invention relates to a spin chuck, apparatus having a spin chuck for manufacturing a piezoelectric resonator piece, a method of manufacturing a piezoelectric resonator piece, a piezoelectric resonator piece, and a piezoelectric resonator.

2. Description of the Related Art

Recent mobile phones and mobile information terminal apparatus include a piezoelectric resonator utilizing quartz or the like which serves as a clock source, a source of timing for control signals, or a source of a reference signal. Various types of piezoelectric resonators of this category are available. One type of such piezoelectric resonators is piezoelectric resonators having what is called a tuning-fork resonator piece. A tuning-fork resonator piece is a piece of quartz in the form of a thin plate including a pair of resonating arms disposed in parallel with each other when viewed in the width direction of the plate and a base on which longitudinal base ends of the pair of resonating arms are integrally secured.

A specific method of forming the outline of a tuning-fork resonator piece is as follows.

First, a metal film is formed on a quartz wafer which is to be formed into a piezoelectric resonator piece, the metal film serving as a metal mask for forming the outline of the resonator piece at a later step. Next, a photoresist mask is applied over the metal film to form a photoresist film. Subsequently, the photoresist film is patterned using photolithography to form a mask to be used for etching the metal film. Thereafter, the metal film is etched using the photoresist film as a mask to pattern the metal film. Finally, the quartz wafer is dry-etched using the metal film pattern as a metal mask. As a result, the quartz wafer is selectively removed to leave the region protected by the metal film pattern, whereby the outline of a piezoelectric resonator piece is formed.

At the above-described step of forming the outline of a piezoelectric resonator piece, the photoresist material must be applied to the surface of the quartz wafer such that the resultant film will have a uniform thickness. The reason is as follows.

For example, when a negative resist material is used as the photoresist material, the thickness of the photoresist film will become irregular. If the photoresist film has regions with an undesirably great thickness, the film may not be sufficiently cured when exposed. The photoresist material is dissolved at a developing step when the material is not sufficiently cured by exposure, and the mask constituted by the photoresist film will therefore have surface defects.

When the metal film is etched using such a photoresist film having surface defects as a mask, parts of the metal film associated with the surface defects are etched, and the surface defects are therefore transferred to the metal film pattern. Further, when the quartz wafer is dry-etched using the metal film pattern having surface defects transferred thereon as a metal mask, the surface defects are transferred to the quartz wafer.

Irregularities of the photoresist film applied to the surface of the quartz wafer becomes surface defects of the mask constituted by the photoresist film, and the defects can result in failures in forming the outline of the piezoelectric resonator piece. It is therefore necessary to apply the photoresist material to the surface of the quartz wafer such that the resultant film will have a uniform thickness.

A method of applying a material to a surface of a quartz wafer using a spin chuck is known (for example, see Patent Document 1).

FIG. 11 is an illustration of a spin chuck 300.

As shown in FIG. 11, a quartz wafer 65 is placed on an absorption plate 310 (which corresponds to “a substrate holding section” described in claims in the present specification), and the quartz wafer 65 is rotated at a high speed while being absorbed onto the plate by a negative pressure, as shown in FIG. 11. A photoresist material is ejected onto a top surface of the quartz wafer 65 from a nozzle which is not shown, and the photoresist material is spread by the centrifugal force in the form of a thin film. Thus, a photoresist film is formed on the top surface of the quartz wafer.
Patent Document 1: JP-A-2007-19317

### SUMMARY OF THE INVENTION

The spin chuck 300 disclosed in Patent Document 2 has the following problem.

The spin chuck 300 disclosed in Patent Document 1 has a circumferential seal rib 312 which is formed on a top surface of the absorption plate 310 so as to extend along a peripheral edge 310a of the plate. The seal rib 312 increases the surface area of the peripheral edge 310a of the absorption plate 310, whereby the area of contact between the circumferential edge and the air is increased.

When the spin chuck 300 rotates, a high pressure is produced around the peripheral edge 310a of the spin chuck 300 as a result of contact between the peripheral edge 310a of the absorption plate 310 and the air, and turbulence R of air is generated to flow under the quartz wafer 65. Mist of the photoresist material generated when the photoresist material is ejected onto the quartz wafer 65 may be transported by the turbulence R to fall on the quartz wafer 65. When the mist of the photoresist material is deposited on the quartz wafer 65, the thickness of the photoresist film becomes uneven, which can result in failures in forming the outline of a piezoelectric resonator piece.

Under the circumstance, it is desirable to provide a spin chuck which can suppress irregularities in the thickness of a film when forming the film by applying a film material to a substrate, an apparatus having such the spin chuck for manufacturing a piezoelectric resonator piece, a method of manufacturing a piezoelectric resonator piece using the manufacturing apparatus, a piezoelectric resonator piece manufactured according to the manufacturing method, and a piezoelectric resonator having the piezoelectric resonator piece.

According to the invention, there is provided a spin chuck rotating a substrate utilizing a centrifugal force while holding one surface of the substrate with a substrate holding section to apply a film material to another surface of the substrate, characterized in that the substrate holding section includes a tapered peripheral part having a peripheral edge where a substrate holding surface and a back surface thereof are connected and in that the other surface of the substrate and the back surface of the substrate holding section smoothly continue with each other with the holding surface of the substrate holding section kept in contact with the other surface of the substrate.

According to the invention, since the area of contact between the peripheral part of the substrate holding section and the air can be kept small, it is possible to suppress the generation of a high pressure around the peripheral part attributable to contact between the peripheral part of the substrate holding section and the air when the substrate is rotated. It is therefore possible to prevent the generation of turbulence of air which can flow into a region under the substrate. Thus, mist of the film material can be prevented from being transported by turbulence to be deposited on the substrate. Therefore, when the film material is applied to form a film, irregularities in the thickness of the film can be suppressed.

The substrate holding section may be formed such that the back surface is sloped from the center of rotation to the peripheral edge to become closer to the substrate.

According to the invention, since the back surface of the substrate holding section is formed as thus described, the substrate holding section can be formed by a simple process, and a reduction in manufacturing cost can be achieved. Therefore, turbulence can be prevented to suppress irregularities in the film thickness at a low cost.

According to the invention, there is provided an apparatus for manufacturing a piezoelectric resonator piece including a spin chuck according to the invention, characterized in that the substrate is a quartz wafer from which a plurality of piezoelectric resonator pieces are cut out and in that the film material is a photoresist material to serve as a mask when the outline of the piezoelectric resonator pieces is formed on the quartz wafer.

According to the invention, when the photoresist material is applied to the quartz wafer to form a photoresist film, irregularities in the thickness of the film can be suppressed. As a result, when the photoresist film is exposed and thereafter developed, the generation of surface defects on the photoresist film can be suppressed, and the outline of the piezoelectric resonator pieces can therefore be precisely formed.

According to the invention, there is provided a method of manufacturing a plurality of piezoelectric resonator pieces from a quartz wafer using the above-described apparatus for manufacturing a piezoelectric resonator piece. The method includes a quartz wafer setting step for setting the quarts wafer on the spin chuck and a photoresist film forming step for forming a film of a photoresist material to serve as a mask when forming the outline of the piezoelectric resonator piece on one surface of the quartz wafer while holding and rotating the quartz wafer.

According to the invention, the area of contact between the peripheral part of the substrate holding section of the spin chuck and the air can be kept small. At the photoresist film forming step, it is therefore possible to suppress the generation of a high pressure around the peripheral part attributable to contact between the peripheral part of the substrate holding section and the air when the substrate is rotated. Thus, the generation of turbulence of air which can flow into a region under the substrate can be prevented. Therefore, mist of the film material can be prevented from being transported by turbulence to be deposited on the substrate, and irregularities in the thickness of the resultant film can be suppressed.

According to the invention, there is provided a piezoelectric resonator piece characterized in that it is manufactured using the above-described manufacturing method.

According to the invention, since the outline of a piezoelectric resonator piece can be precisely formed, the piezoelectric resonator piece can be provided with high durability and high performance.

According to the invention, there is provided a piezoelectric resonator characterized in that it includes a piezoelectric resonator piece according to the above-described manufacturing method.

According to the invention, the piezoelectric resonator piece can be provided with high durability and high performance.

According to the invention, since the area of contact between the peripheral part of the substrate holding section and the air can be kept small, it is possible to suppress the generation of a high pressure around the peripheral part attributable to contact between the peripheral part of the substrate holding section and the air when the substrate is rotated. It is therefore possible to prevent the generation of turbulence of air which can flow into a region under the substrate. Thus, mist of the film material can be prevented from being transported by turbulence to be deposited on the substrate. Therefore, when the film material is applied to form a film, irregularities in the thickness of the film can be suppressed.

### BRIEF DESCRIPTION OF THE DRAWINGS

FIG. 1 is a plan view of a piezoelectric resonator piece;

FIG. 2 is a sectional view taken along the line A-A in FIG. 1;

FIG. 3 is a flow chart of steps for manufacturing a piezoelectric resonator piece;

FIG. 4 is a side sectional view of a spin chuck;

FIG. 5 is an illustration for explaining a photoresist film forming step;

FIG. 6 is an external perspective view of a piezoelectric resonator;

FIG. 7 is a plan view of the piezoelectric resonator shown in FIG. 6 illustrated with a lid substrate removed to show an internal configuration;

FIG. 8 is a sectional view taken along the line B-B in FIG. 7;

FIG. 9 is an exploded perspective view of the piezoelectric resonator shown in FIG. 6;

FIG. 10 is an exploded perspective view of a wafer body; and

FIG. 11 is an illustration of a spin chuck according to the related art.

### DETAILED DESCRIPTION OF THE PREFERRED EMBODIMENTS

### (Piezoelectric Resonator Piece)

First, a piezoelectric resonator piece according to an embodiment of the invention will be described with reference to the drawings.

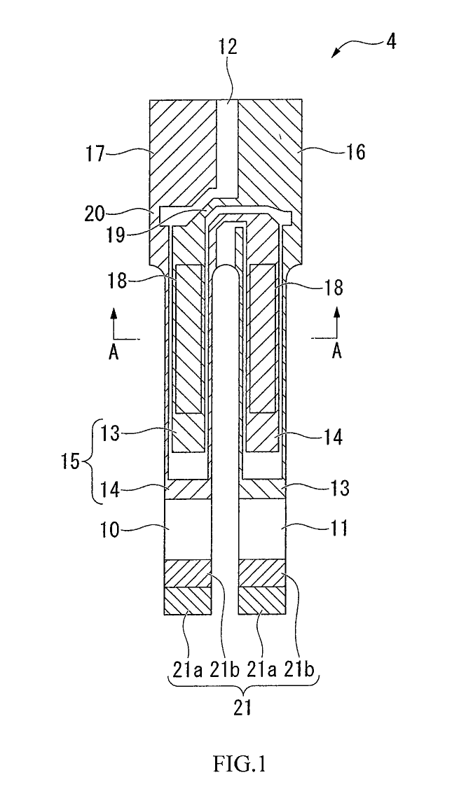

FIG. 1 is a plan view of a piezoelectric resonator piece 4.

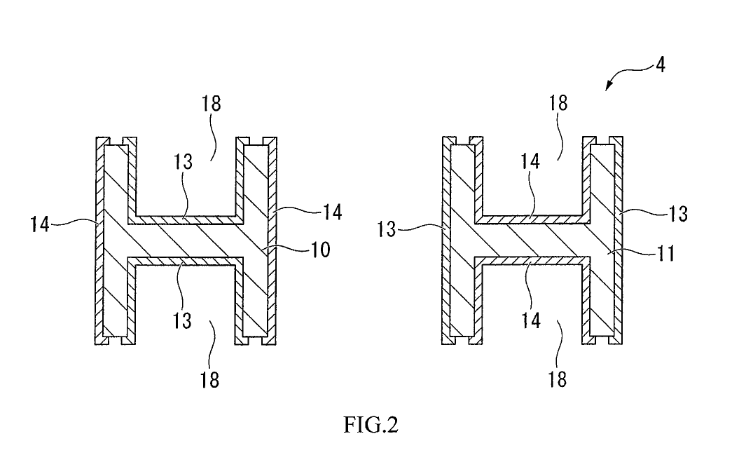

FIG. 2 is a sectional view taken along the line A-A in FIG. 1.

As shown in FIG. 1, the piezoelectric resonator piece 4 of the present embodiment is a tuning-fork type resonator piece formed of quartz, and it oscillates when a predetermined voltage is applied thereto. The piezoelectric resonator piece 4 includes a pair of resonating arms 10 and 11 disposed in parallel with each other, a base section 12 to which base ends of the pair of resonating arms 10 and 11 are integrally secured, and grooves 18 formed on principal surfaces of both of the pair of resonating arms 10 and 11. The grooves 18 are formed to extend in the longitudinal direction of the resonating arms 10 and 11 from the base ends of the resonating arms 10 and 11 up to positions substantially in the middle of the arms.

The piezoelectric resonator piece 4 has excitation electrode groups 15 each including a first excitation electrode 13 and a second excitation electrode 14 formed on outer surfaces of the pair of resonating arms 10 and 11 for resonating the pair of resonating arms 10 and 11, mount electrodes 16 and 17 formed on the base section 12 for packaging the piezoelectric resonator piece 4, and lead-out electrodes 19 and 20 for electrically connecting the first excitation electrodes 13 and the second excitation electrodes 14 to the mount electrodes 16 and 17.

The excitation electrode groups 15 and the lead-out electrodes 19 and 20 are formed as single-layer films from chromium which is the same material as used for backing layers of the mount electrodes 16 and 17 to be described later. Therefore, the excitation electrode groups 15 and the lead-out electrodes 19 and 20 can be formed at the same time when the backing layers of the mount electrodes 16 and 17 are formed. However, the invention is not limited to such a material, and the excitation electrode groups 15 and the lead-out electrodes 19 and 20 may be formed from nickel, aluminum, titanium, or the like.

The excitation electrode groups 15 are electrodes for resonating the pair of resonating arms 10 and 11 in the direction of moving them toward and away from each other at a predetermined frequency. The first excitation electrodes 13 and the second excitation electrodes 14 forming the excitation electrode groups 15 are patterned and formed on outer surfaces of the pair of resonating arms 10 and 11 in electrical isolation from each other (see FIG. 2). The first excitation electrodes 13 and the second excitation electrodes 14 are electrically connected through the lead-out electrodes 19 and 20 to the mount electrodes 16 and 17 to be described later on both principal surfaces of the base section 12.

The mount electrodes 16 and 17 are multi-layer films having chromium and gold layers, and the electrodes are provided by forming films of chromium which exhibits high adhesion to quartz as backing layers and thereafter forming thin films of gold as finishing layers on the surface of the chromium films. However, the invention is not limited to such a configuration. For example, films having layers of chromium and nichrome may be formed as backing layers, and thin films of gold to serve as finishing layers may be formed thereafter on the surface of the backing layers.

The tips of the pair of resonating arms 10 and 11 are coated with weight metal films 21 for adjusting the arms such that they oscillate within a predetermined frequency range (frequency adjustment). The weight metal films 21 are made of different films, i.e., a coarse adjustment film 21a used for coarse frequency adjustment and a fine adjustment film 21b used for fine adjustment. The frequency of the pair of resonating arms 10 and 11 can be kept within a nominal frequency range of the device by adjusting the frequency using the coarse adjustment film 21a and the fine adjustment film 21b.

### (Method of Manufacturing Piezoelectric Resonator Piece)

Steps for manufacturing the a piezoelectric resonator piece 4 as described above will now be described with reference to a flow chart.

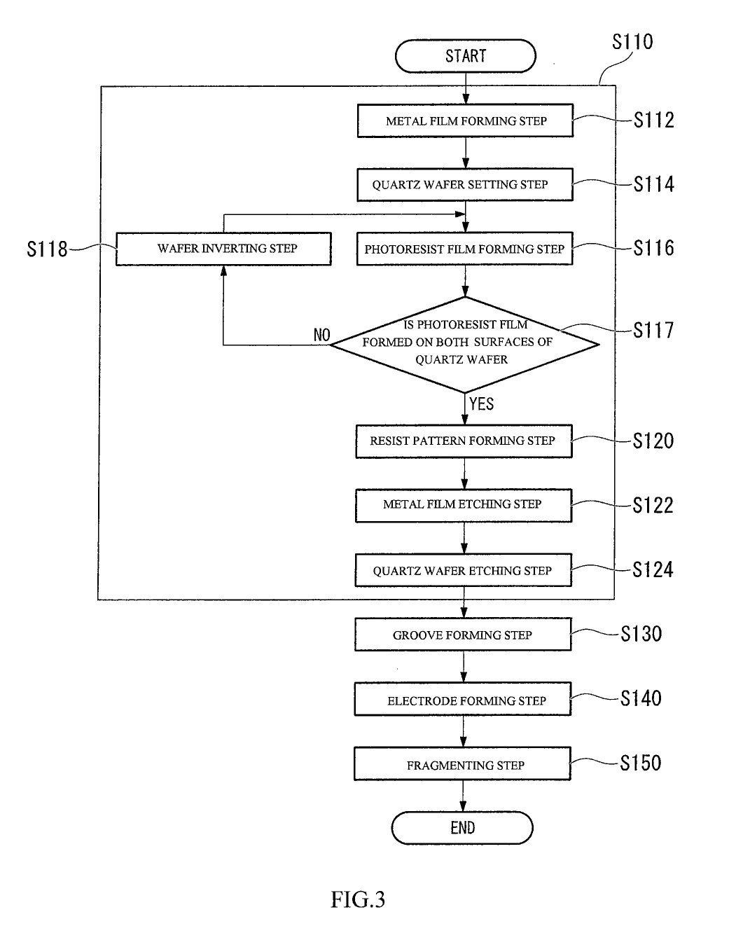

FIG. 3 is a flow chart of steps for manufacturing a piezoelectric resonator piece 4.

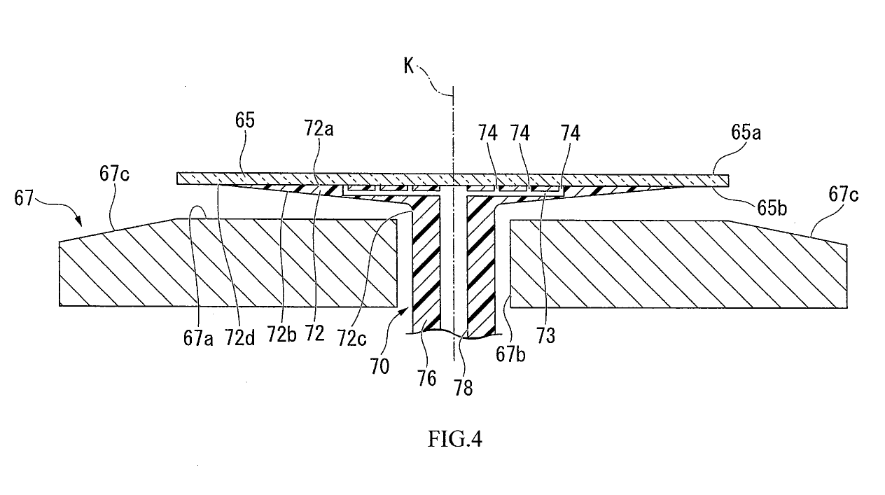

The steps for manufacturing a piezoelectric resonator piece 4 include an outline forming step S110 for forming the outline of a piezoelectric resonator piece 4 on a quartz wafer 65 (see FIG. 4), a groove forming step S130 for forming recesses to serve as grooves 18 (see FIG. 2) of the piezoelectric resonator piece 4 later, an electrode forming step S140 for forming electrodes, and a fragmenting step S150 for cutting the piezoelectric resonator piece 4 from the quartz wafer 65. Details of each step will now be described. In the following description, one of two principal surfaces of the quartz wafer 65, i.e., an upper principal surface of the wafer will be referred to as “surface 65a”, and a lower principal surface will be referred to as “surface 65b”.

### (Outline Forming Step S110)

The outline forming step S110 includes a metal film forming step S112 for forming a metal film on a surface of the quartz wafer 65, a quartz wafer setting step S114 for setting the quartz wafer 65 on a spin chuck 70 (see FIG. 4) which will be described later, and a photoresist film forming step S116 for forming a photoresist film on the quartz wafer 65. Further, the step S110 includes a resist pattern forming step S120 for forming a resist pattern from the photoresist film using a photolithographic technique, a metal film etching step S122 for etching the metal film, and a quartz wafer etching step S124 for etching the quartz wafer 65.

### (Metal Film Forming Step S112)

At the metal film forming step S112, a metal film is formed on the quartz wafer 65 which has been precisely finished to a predetermined thickness through a polishing process. For example, the metal film is a multi-layer film formed by a backing film made of chromium and a protective film made of gold, and each of the films is formed using a sputtering process, a vacuum deposition process, or the like. A part of the metal film formed at the metal film forming step S112 serves as a metal mask for etching the quartz wafer 65 at the quartz wafer etching step S124 and the groove forming step S130 which will be performed later.

### (Quartz Wafer Setting Step S114, Spin Chuck)

Next, the quartz wafer setting step S114 is performed to set the quartz wafer 65 on the spin chuck 70.

FIG. 4 is a side sectional view of the spin chuck 70.

The spin chuck 70 will be first described with reference to FIG. 4, and the quartz wafer setting step S114 will be thereafter described. In FIG. 4, the metal film formed on the surface of the quartz wafer 65 is omitted for clearer illustration. The center axis of the spin chuck 70 is represented by K.

The spin chuck 70 is formed from a resin or metal, and it has a substrate holding section 72 for holding the quartz wafer 65 and a column section 76 for supporting the substrate holding section 72.

The substrate holding section 72 is a sheet-like member which is substantially circular when viewed from above. The diameter of the substrate holding section 72 is set smaller than the diameter of the quartz wafer 65.

A holding surface 72a of the substrate holding section 72 is formed flatly, and the quartz wafer 65 can be placed on the holding surface with a surface of the quartz wafer 65 in contact therewith.

A plurality of absorption holes 74 are formed throughout the holding surface 72a of the substrate holding section 72. The absorption holes 74 are connected to a vacuum pump which is not shown through absorption channels 73 formed in the substrate holding section 72 and an absorption channel 78 formed in the column section 76 which will be described later. When evacuation is performed by the vacuum pump, the quartz wafer 65 is absorbed to the substrate holding section 72 by a negative pressure and held on the holding surface 72a of the substrate holding section 72.

The substrate holding section 72 has a tapered peripheral part 72d whose edge connects the surface 72a holding the quartz wafer 65 and a back surface 72b thereof. Specifically, the back surface 72b of the substrate holding section 72 is formed in the form of a slope gradually extending upward from a central part 72c of the substrate holding section 72 to the peripheral part 72d, and the substrate holding section 72 is formed with a thickness which decreases from a maximum value at the central part 72c toward the peripheral part 75d. Therefore, when the quartz wafer 65 is placed on the substrate holding section 72 at the quartz wafer setting step S114 which will be described later, the back surface 72b of the substrate holding section 72 is furthest from the quartz wafer at the central part 72c and the surface gradually becomes closer to the wafer toward the peripheral part 72d when viewed sideway. Thus, no large step is formed between the back surface 72b of the substrate holding section 72 and the quartz wafer 65, and the peripheral part 72d of the substrate holding section 72 therefore has a quite small surface area.

The column section 76 is provided substantially in the middle of the back surface 72b of the substrate holding section 72.

The column section 76 is a hollow cylindrical member, and it is formed integrally with the substrate holding section 72 such that the center axis of the section substantially coincides with the center axis of the substrate holding section 72.

The absorption channel 78 is formed in the column section 76, and the channel is connected to the vacuum pump which is not shown. The absorption channel 78 is in communication with the absorption channels 73 and the absorption holes 74 formed in the substrate holding section 72.

The column section 76 is connected to a motor which is not shown. When the motor is driven for rotation, the spin chuck 70 rotates about the center axis K serving as a center of rotation.

A rectifying plate 67 for rectifying flows of air may be provided under the substrate holding section 72 so as to surround the column section 76. For example, the rectifying plate 67 is a member made of resin or metal substantially in the form of a disk when viewed from above, the member having an outline formed greater than that of the quartz wafer 65. A through hole 67b is formed in the middle of the rectifying plate 67, and the column section 76 is inserted through the hole.

A top surface 67a of the rectifying plate 67 is contiguous with a downward inclined surface 67c which is located outwardly of the quartz wafer 65. As will be described later, air flows generated on the surface of the quartz wafer 65 when the wafer is rotated flow along the inclined surface 67c.

### (Quartz Wafer Setting Step S114)

The quartz wafer setting step S114 is performed to set the quartz wafer 65 having a metal film formed thereon on the spin chuck 70 configured as thus described.

At the quartz wafer setting step S 114, the quartz wafer 65 is set on the substrate holding section 72 of the spin chuck 70. Specifically, the quartz wafer 65 is oriented such that the surface 65b faces downward and placed on the substrate holding section 72 with the surface 65b of wafer put in contact with the holding surface 72a of the holding section. A positioning mechanism, which is not shown, is provided between the surface 65b of the quartz wafer 65 and the holding surface 72a of the substrate holding section 72 to place the quartz wafer 65 such that the center axis thereof substantially coincides with the center axis K of the spin chuck 70.

### (Photoresist Film Forming Step S116)

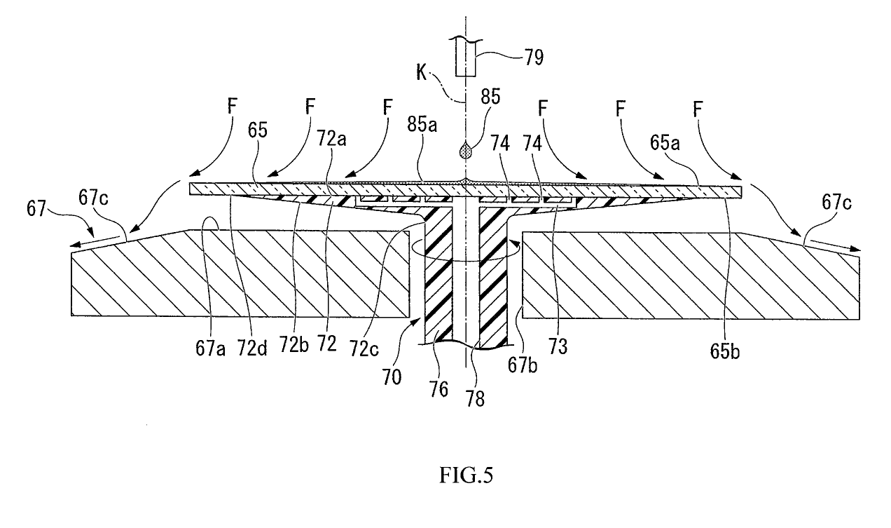

FIG. 5 is an illustration for explaining the photoresist film forming step S116.

As shown in FIG. 5, the photoresist film forming step S116 for forming a photoresist film on the quartz wafer 65 is started by applying a photoresist material 85 on the wafer. The photoresist material 85 applied in the present embodiment is what is called a negative photoresist material. That is, the material is cured when exposed, and an exposed part of the material remains after a development process.

At the photoresist film forming step S116, evacuation is first performed by the vacuum pump (not shown) to absorb the surface 65b of the quartz wafer 65 onto the substrate holding section 72 through vacuum absorption. At the same time, the motor (not shown) is driven for rotation to rotate the spin chuck 70 and the quartz wafer 65 at a high speed.

Next, as shown in FIG. 5, an appropriate amount of the photoresist material 85 is dropped toward the surface 65a of the quartz wafer 65 from a nozzle 79 disposed above the quartz wafer 65 to extend along the center axis K.

The photoresist material 85 dropped and deposited on the surface 65a of the quartz wafer 65 is spread by a centrifugal force in the form of a thin film extending substantially from the center of the quartz wafer 65 toward the periphery thereof. Thus, a photoresist film 85a is formed on the surface 65a of the quartz wafer 65.

As a result of the rotation of the quartz wafer 65, air flows F are generated on the surface 65a of the quartz wafer 65 to flow from the center of the quartz wafer 65 toward the periphery thereof. Mist of the photoresist material 85 generated when the photoresist material 85 is dropped on the surface 65a of the quartz wafer 65 I transported by the air flows F from the center of the quartz wafer 65 toward the periphery thereof.

As shown in FIG. 11, in the case of the spin chuck 300 disclosed in Patent Document 1, a high pressure is generated around the peripheral edge 310a of the absorption plate 310 (which corresponds to the substrate holding section 72 of the present embodiment) as a result of contact between the peripheral edge 310a and the air, and turbulence R of air which can flow under the quartz wafer 65 is generated. As a result, according to the related art, the mist of the photoresist material 85 can be transported to a region under the quartz wafer 65 by turbulence R to be deposited on the quartz wafer 65.

In the spin chuck 70 of the present embodiment, the substrate holding section 72 is tapered from the central part 72c toward the peripheral part 72d such that the back surface 72b becomes closer to the quartz wafer 65. Thus, the area of contact between the peripheral part 72d of the substrate holding section 72 and the air can be kept small. It is therefore possible to prevent a high pressure from being generated around the peripheral part 72d as a result of contact between the peripheral part 72d of the substrate holding section 72 and the air. Thus, the generation of turbulence of air flowing into a region under the substrate is prevented. In the present embodiment, since the rectifying plate 67 is provided, the mist of the photoresist material transported by air flows F toward the periphery of the quartz wafer 65 is guided so as to flow outwardly of the quartz wafer 65 along the inclined surface 67c of the rectifying plate 67, whereby the mist is discharged from an exhaust hole which is not shown.

### (Surface Checking Step S117 and Wafer Inverting Step S118)

When it is found that the photoresist film 85a is not formed on the surface 65b of the quartz wafer 65 or the bottom surface of the wafer after the photoresist film 85a is formed on the surface 65a of the quartz wafer 65 (S117), the quartz wafer 65 is inverted to reverse the positional relationship between the surfaces 65a and 65b, and the photoresist film forming step S116 is carried out again on the quartz wafer 65. Thus, the photoresist film 85a is formed throughout the surfaces 65a and 65b of the quartz wafer 65.

### (Resist Pattern Forming Step S120)

Next, the resist pattern forming step S120 is performed to pattern the photoresist film 85a formed as described above using a photolithographic technique. Specifically, photo-masks (not shown) are set on both surfaces of the quartz wafer 65 to expose them through irradiation with ultraviolet light. As described above, the photoresist material 85 used in the present embodiment is a negative photoresist material. Therefore, when the wafer is immersed in a developer after exposure, the photoresist film 85a remains unremoved in regions thereof which have been cured by being exposed to ultraviolet light, and uncured regions of the photoresist film 85a which have not been exposed to ultraviolet light are selectively removed.

If the photoresist film 85a has irregularities in thickness and therefore includes regions having an undesirably great thickness, such regions may not be sufficiently cured by exposure and may consequently dissolved and removed when development is carried out. Since the resist pattern of the remaining photoresist film 85a may have surface defects which can cause failures in forming the outline of a piezoelectric resonator piece 4.

In the present embodiment, the generation of turbulence attributable to the rotation of the spin chuck 70 is suppressed at the photoresist film forming step S116 to form the photoresist film 85a while preventing deposition of mist of the photoresist material 85 on the quartz wafer 65. Thus, irregularities in the thickness of the photoresist film 85a can be suppressed to allow a resist pattern to be formed without surface defects at the resist pattern forming step S120.

### (Metal Film Etching Step S122)

Next, the metal film etching step S122 is performed to etch the metal film formed at the metal film forming step S112 using the pattern of the remaining photoresist film 85a as a mask. At this step, regions of the metal film which are not masked by the photoresist film 85a are selectively removed. Thereafter, the patterned resist mask 85a is removed. Thus, metal film patterns associated with the outline of the piezoelectric resonator piece 4 are formed on the surfaces 65a and 65b of the quartz wafer 65.

### (Quartz Wafer Etching Step S124)

Next, the quartz wafer etching step S124 is performed to dry-etch both surfaces of the quartz wafer 65 using the metal film patterns as a mask. Thus, regions of the wafer which are not masked by the metal film patterns are selectively removed, whereby piezoelectric plates each having the shape of the outline of a piezoelectric resonator piece 4 can be formed. Each of the piezoelectric plates is connected to the dry-etched quartz wafer 65. The outline forming step S110 is thus completed.

### (Groove Forming Step S130)

Next, the groove forming step S130 is performed to form recesses to serve as the grooves 18 (see FIG. 1) on each piezoelectric plates. Specifically, a photoresist film (not shown) is formed on each piezoelectric plate using a spray coat process, and the photoresist film is patterned using a photolithographic technique. Subsequently, the metal film on the plate is etched using the resist pattern as a mask to pattern the metal film with regions for forming the recesses left unmasked. The quartz wafer 65 is etched using the metal film as a mask, and the metal film is thereafter removed, whereby the recesses can be formed on principal surfaces of each piezoelectric plates.

### (Electrode Forming Step S140)

Next, the electrode forming step S140 is performed to form electrodes on outer surfaces of each piezoelectric plate formed in the shape of the outline of a piezoelectric resonator piece 4. At the electrode forming step S140, a metal film is first formed and patterned to form excitation electrode groups 15, lead-out electrodes 19 and 20, mount electrodes 16 and 17, and weight metal films 21 (see FIG. 1 for those features). Next, coarse adjustment of the resonance frequency of the piezoelectric plate is carried out. The adjustment is carried out by irradiating coarse adjustment films 21a included in the weight metal films 21 with laser light to evaporate a part of the films to change the weights of resonating arms 10 and 11. Thus, the electrode forming step S140 is completed.

### (Fragmenting Step S150)

Finally, the fragmenting step S150 is performed to fragment the quartz wafer 65 into a plurality of piezoelectric resonator pieces 4 by cutting connecting portions connecting the piezoelectric plates to the quartz wafer 65. Thus, a plurality of tuning-fork type piezoelectric resonator pieces 4 can be manufactured at a time from a single wafer. At this point, the process of manufacturing piezoelectric resonator pieces 4 is terminated, and a plurality of piezoelectric resonator pieces 4 as shown in FIG. 4 can be obtained.

### (Advantages)

According to the present embodiment, since the area of contact between the peripheral part 72d of the substrate holding section 72 and the air can be kept small, the generation of a high pressure around the peripheral part 72d of the substrate holding section 72 can be suppressed to prevent the generation of turbulence of air which can flow into a region under the quartz wafer 65. It is therefore possible to prevent mist of the photoresist material 85 from being transported by the turbulence to be deposited on the quartz wafer 65. Thus, when the photo-resist film 85a is formed on the wafer by applying the photoresist material 85, irregularities in the film thickness can be suppressed.

According to the present embodiment, since the back surface 72b of the substrate holding section 72 is formed as described above, processes for forming the substrate holding section 72 are facilitated, and the processing cost can therefore be kept small. Thus, turbulence can be prevented to suppress irregularities in the film thickness at a low cost.

According to the present embodiment, when the photo-resist film 85a is formed on the quartz wafer 65 by applying the photoresist material 85, irregularities in the film thickness can be suppressed. Since the generation of surface defects on the photoresist film 85a can therefore be suppressed when the photoresist film 85a is exposed and is thereafter developed, the outline of a piezoelectric resonator piece 4 can be precisely formed.

According to the present embodiment, the area of contact between the peripheral part 72d of the substrate holding section 72 of the spin chuck 70 and the air can be kept small. Therefore, at the photoresist film forming step S116, it is possible to suppress the generation of a high pressure around the peripheral part 72d attributable to contact between the peripheral part 72d of the substrate holding section 72 and the air. Thus, the generation of turbulence of air which can flow into a region under the quartz wafer 65 can be prevented. It is therefore possible to prevent mist of the photoresist material 85 from being transported by the turbulence to be deposited on the quartz wafer 65. Thus, irregularities in the thickness of the resultant film can be suppressed.

According to the present embodiment, a piezoelectric resonator piece 4 having high durability and performance can be obtained because the outline of the component can be precisely formed.

### (Piezoelectric Resonator)

A piezoelectric resonator 1 will now be described as an example of a package 9 including the piezoelectric resonator piece 4 manufactured according to the above-described manufacturing method.

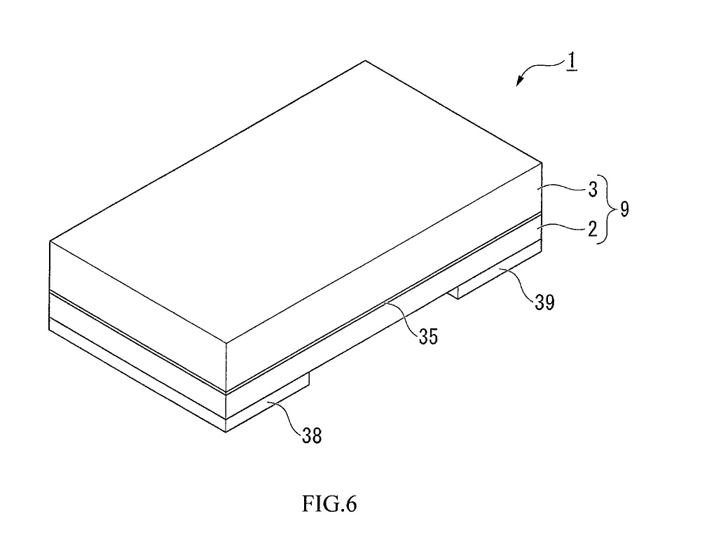

FIG. 6 is an external perspective view of the piezoelectric resonator 1.

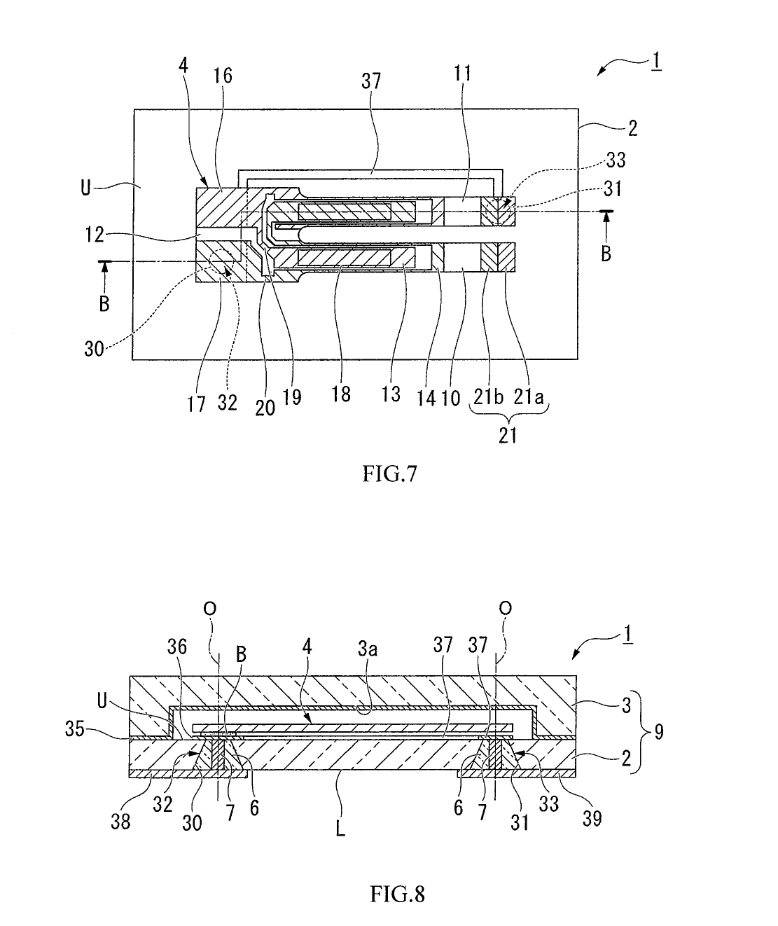

FIG. 7 is a plan view of the piezoelectric resonator 1 illustrated with a lid substrate 3 removed to show an internal configuration.

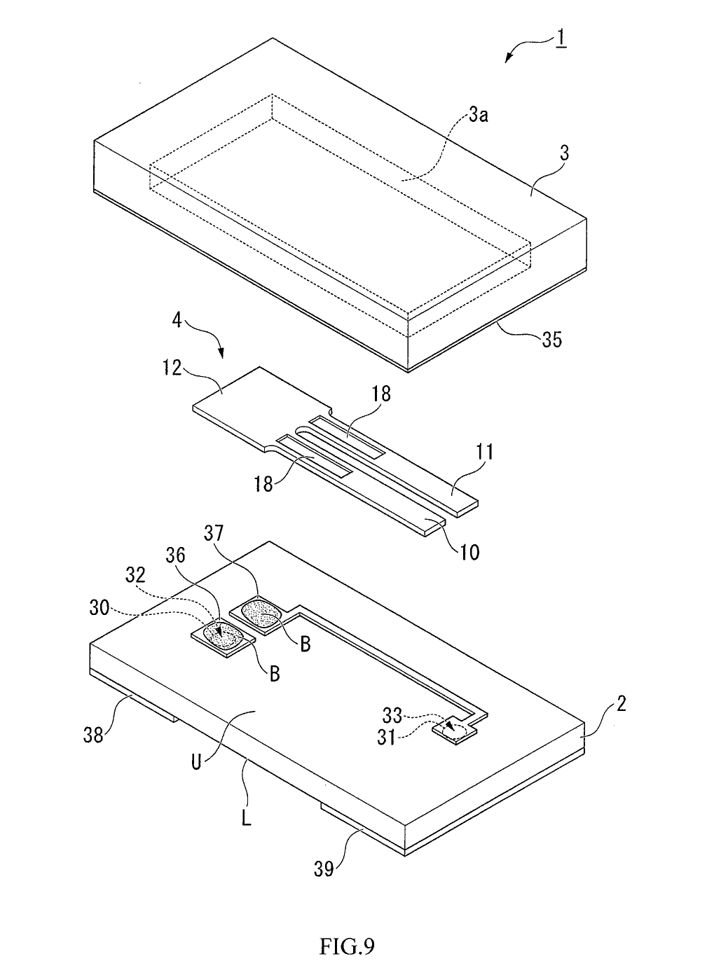

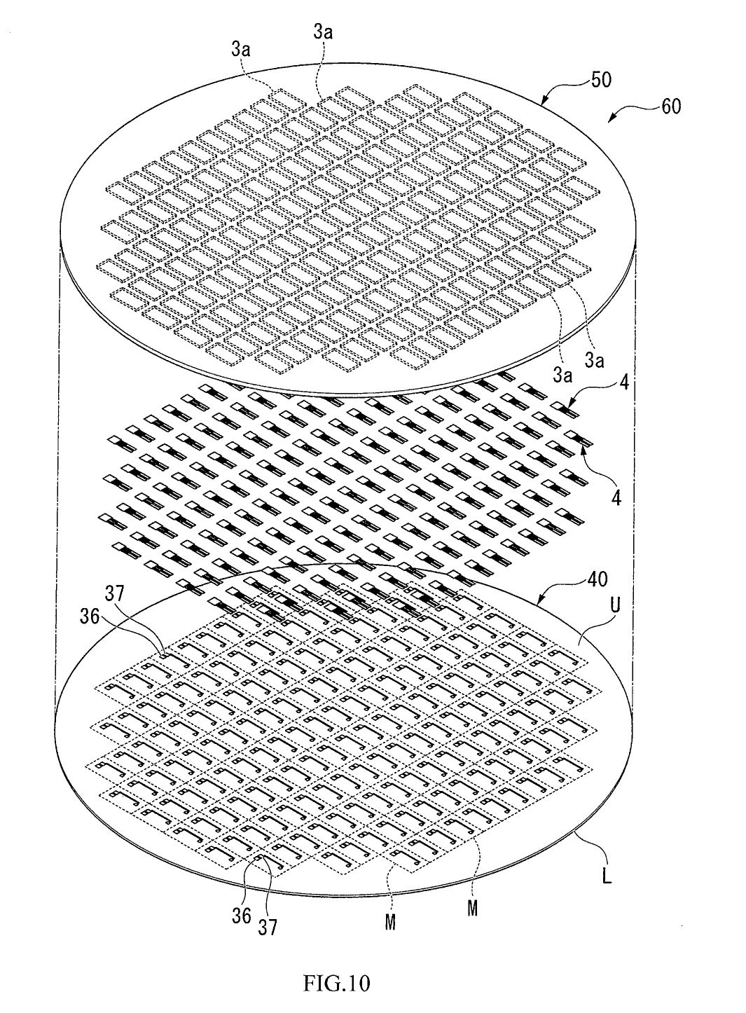

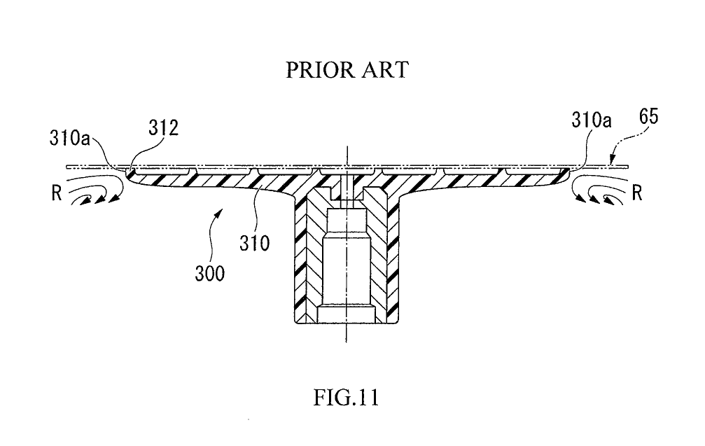

FIG. 8 is a sectional view taken along the line B-B in FIG. 7.

FIG. 9 is an exploded perspective view of the piezoelectric resonator 1 shown in FIG. 6.

For clearer illustration, excitation electrodes 13 and 14 which will be described later, lead-out electrodes 19 and 20, mount electrodes 16 and 17, and weight metal films 21 are omitted in FIG. 9.

As shown in FIG. 6, the piezoelectric resonator 1 of the present embodiment is a surface mount type piezoelectric resonator 1 having a package 9 including a base substrate 2 and a lid substrate 3 combined with each other with a bonding film 35 interposed therebetween using anodic bonding and a piezoelectric resonator piece 4 contained in a cavity 3a of the package 9.

As shown in FIG. 8, the base substrate 2 and the lid substrate 3 are substrates made of a glass material such as soda-lime glass which can be combined using anodic bonding, and the substrates are substantially in the form of plates. The cavity 3a for accommodating the piezoelectric resonator piece 4 is formed on the side of the lid substrate 3 where a surface of the substrate to be bonded with the base substrate 2 is provided.

A bonding film 35 (bonding material) to be used for anodic bonding is formed throughout the surface of the lid substrate 3 to be bonded with the base substrate 2. The bonding film 35 is formed to cover not only the entire inner surface of the cavity 3a but also a frame region around the cavity 3a. While the bonding film 35 of the present embodiment is formed of aluminum, the bonding film 35 may alternatively be formed of chromium or silicon. The bonding film 35 and the base substrate 2 are combined using anodic bonding to vacuum-seal the cavity 3a.

The piezoelectric resonator 1 includes penetrating electrodes 32 and 33 which penetrate through the base substrate 2 in the thickness direction thereof to establish continuity between the interior of the cavity 3a and the exterior of the piezoelectric resonator 1. The penetrating electrodes 32 and 33 are formed by metal pins 7 which are disposed in through holes 30 and 31 penetrating through the base substrate 2 to electrically connect the piezoelectric resonator piece 4 to the exterior of the package and cylindrical bodies 6 which fill the gaps between the through holes 30 and 31 and the metal pins 7. Although the penetrating electrode 32 will be described below by way of example, the description equally applies to the penetrating electrode 33. Electrical connection between the penetrating electrode 33, a routing electrode 37, and an external electrode 39 is the same as electrical connection between the penetrating electrode 32, a routing electrode 36, and the external electrode 39.

The through hole 30 is formed such that its inner diameter gradually increases from the value of the same on a top surface U of the base substrate 2 toward a bottom surface L of the substrate, and the hole is formed such that a section thereof including the center axis 0 of the hole has a tapered shape.

The metal pin 7 is a conductive rod-shaped member formed from a metal material such as silver, a nickel alloy, or aluminum, and it is molded using a forging or pressing process. Preferably, the metal pin 7 is formed from a metal having a linear expansion coefficient similar to that of the glass material from which the base substrate 2 is formed, e.g., an alloy containing 58% iron and 42% nickel by weight (42 alloy).

The cylindrical body 6 is formed by sintering paste-like glass frit. The metal pin 7 is disposed in the middle of the cylindrical body 6 to penetrate through the same, and the cylindrical body 6 is rigidly secured to the metal pin 7 and in the through hole 30.

As shown in FIG. 9, a pair of routing electrodes 36 and 37 is patterned on the top surface U of the base substrate 2. A bump B made of gold or the like is formed on each of the pair of routing electrodes 36 and 37, and the pair of mount electrodes of the piezoelectric resonator piece 4 are mounted using the bumps B. The mount electrode 16 of the piezoelectric resonator piece 4 (see FIG. 7) is in continuity with the penetrating electrode 32 through the routing electrode 36, and the other mount electrode 17 (see FIG. 7) is in continuity with the other penetrating electrode 33 through the other routing electrode 37.

A pair of external electrodes 38 and 39 are formed on the bottom surface L of the base substrate 2. The pair of external electrodes 38 and 39 are formed at both longitudinal ends of the base substrate 2 and are electrically connected to the pair of penetrating electrodes 32 and 33, respectively.

To activate the piezoelectric resonator 1 having such a configuration, a predetermined driving voltage is applied to the external electrodes 38 and 39 formed on the base substrate 2. Since a voltage can be applied to the first excitation electrode 13 and the second excitation electrode 14 of the piezoelectric resonator piece 4 as thus described, the pair of resonating arms 10 and 11 can be oscillated at a predetermined frequency in the directions of moving them toward and away from each other. The piezoelectric resonator 1 can be used as a clock source, a source of timing for control signals, or a source of a reference signal utilizing oscillation of the pair of resonating arms 10 and 11.

### (Advantage)

The piezoelectric resonator 1 of the present embodiment can be provided with high durability and performance because the piezoelectric resonator 1 has the piezoelectric resonator piece 4 whose outline is precisely formed.

The invention is not limited to the above-described embodiment.

The tuning fork type piezoelectric resonator piece 4 of the embodiment is manufactured using a manufacturing method utilizing the spin chuck 70 according to the invention. The manufacturing method utilizing the spin chuck 70 according to the invention is not limited to tuning fork type piezoelectric resonator pieces, and the method may be applied to, for example, AT-cut type piezoelectric resonator pieces (thickness slip piezoelectric resonator pieces). The spin chuck 70 according to the invention may be used to manufacture electronic components other than piezoelectric resonator pieces.

The method of manufacturing the piezoelectric resonator piece 4 according to the embodiment employs a negative resist material as the photoresist material 85. However, the invention is not limited to negative resist materials, and positive resist materials may alternatively be used.

In the present embodiment, the rectifying plate 67 for rectifying air flows is provided under the substrate holding section 72 of the spin chuck 70 to surround the column section 76. The advantages of the embodiment can be achieved without the rectifying plate 67. However, the embodiment is more advantageous in that mist of the photoresist material 85 transported toward the periphery of the quartz wafer 65 can be guided outwardly of the quartz wafer 65 along the inclined surface 67c of the rectifying plate 67 to be smoothly discharged from the exhaust hole.

An inert gas such as nitrogen may be passed upward through a space between an inner circumferential surface of a through hole 67b formed in the middle of the rectifying plate 67 and an outer circumferential surface of the column section 76 of the spin chuck 70. After flowing through the space upward, the inert gas is guided outwardly of the quartz wafer 65 along the back surface 72b of the spin chuck. Thus, the deposition of mist of the photoresist material 85 on the quartz wafer 65 can be reliably suppressed.

In the present embodiment, the back surface 72b of the substrate holding section 72 is formed as an inclined surface which is inclined to gradually extend upward from the central part 72c of the substrate holding section 72 toward the peripheral part 72d. However, the back surface 72b of the substrate holding section 72 may be an upwardly curved surface which is formed such that the thickness of the substrate holding section 72 becomes small from a maximum value at the central part 72c toward the peripheral part 72d. However, the embodiment is more advantageous than such alternatives in that the embodiment allows a resonator to be formed through simpler processes at a lower cost.

What is claimed is:

1. A spin chuck rotating a substrate utilizing a centrifugal force while holding one surface of the substrate with a substrate holding section to apply a film material to another surface of the substrate, wherein
the substrate holding section comprises a tapered peripheral part having a peripheral edge where a substrate holding surface and a back surface thereof are connected; and
the other surface of the substrate and the back surface of the substrate holding section smoothly continue with each other with the holding surface of the substrate holding section kept in contact with the other surface of the substrate.

2. A spin chuck according to claim 1, wherein the substrate holding section is formed at an inclination such that the back surface is sloped from the center of rotation to the peripheral edge to become closer to the substrate.

3. An apparatus for manufacturing a piezoelectric resonator piece comprising a spin chuck according to claim 1, wherein:
the substrate is a quartz wafer from which a plurality of piezoelectric resonator pieces are cut out; and
the film material is a photoresist material to serve as a mask when the outline of the piezoelectric resonator pieces is formed on the quartz wafer.
